(19) United States
(12) Patent Application Publication
(10) Pub. No.: US 2008/0192432 A1
(43) Pub. Date: Aug. 14, 2008

(54) HEAT SINK STRUCTURE FOR CAR POWER ADAPTER

(75) Inventors: Yueh-Hua Hsu Huang, Chung-Ho City (TW); Lien-Huang Yang, Chung-Ho City (TW); Chang-Shou Wu, Chung-Ho City (TW)

Correspondence Address: PAI PATENT & TRADEMARK LAW FIRM, 1001 FOURTH AVENUE, SUITE 3200, SEATTLE, WA, 98154, US

(73) Assignee: JAZZ HIPSTER CORPORATION, Chung-Ho City (TW)

(21) Appl. No.: 11/672,623

(22) Filed: Feb. 8, 2007

(51) Int. Cl. H05K 7/20

(52) U.S. Cl. 361/697

(57) ABSTRACT

An improved heat sink structure for car power adapter has an air-in vent on the lateral side of the power adapter, an air-out vent on an upper housing of the power adapter, a circuit board disposed within the power adapter wherein a fan is mounted on the circuit board and a heat sink is disposed on the fan. The present invention implements the heat sink with the fan so as to suck cold air into the power adapter via the air-in vent. When the electronic elements on the circuit board generate heat, the heat sink is capable of conducting the heat from the electronic elements of the circuit board and the cold air enhances the efficiency in heat exchange. Subsequently, the heated air can be exhausted to outside via the air-out vent by the fan, thereby prolonging the lifetime and reducing the breakdown possibilities of the heat sink structure.

### BACKGROUND OF THE INVENTION

1. Field of the Invention

The present invention relates to an improved heat sink structure for car power adapter; particularly, it relates to an improved heat sink structure for car power adapter in which at least one electronic component on a circuit board of the power adapter is mounted with a heat sink and a fan and thereby the heat caused by electronic parts can be removed efficiently and rapidly.

2. Description of the Prior Art

Many electric devices (such as car vacuum cleaner and air pump) may be used within a car by plugging an exclusive car plug into the car's cigarette lighter. Household electric appliances (such as laptop computer) cannot be directly used in cars because the plug of the household electric appliances is not the same as the exclusive car plug; they are per two different standards.

Therefore, power adapters with an adaptive plug have been developed for carrying out the purpose of adapting the power plug so that the household electric appliances can be used in cars. However, the body of such power adapters is normally big and thus occupies a relatively significant space inside the car. When the interior space in car is limited, the power adapter causes an inconvenience if its body is too big. For eliminating the above drawbacks, the present invention provides a power adapter with a small body.

In view of the above, the conventional power adapter still has many drawbacks and should be improved.

In order to correct the preceding defects of the conventional power adapter, the inventor of the present invention has given every effort in experimentation and innovation. After years the present invention of improved heat sink structure for car power adapter is provided.

### SUMMARY OF THE INVENTION

One of the objects of the present invention is to provide an improved heat sink structure of car power adapter in which a heat sink and a fan are disposed on electronic components of the circuit board within the power adapter, the cold air sucked into the power adapter and passing through the heat sink will take the heat energy away from the heat sink, and subsequently the heated air is exhausted out of the power adapter by the fan so as to achieve efficient and rapid heat removal for electronic components.

Another one of the objects of the present invention is to provide an improved heat sink structure of car power adapter having advantages in small volume, good heat removing ability, and low manufacturing cost.

A further one of the objects of the present invention is to provide an improved heat sink structure of car power adapter with efficient heat removing ability so as to improve the lifetime and reduce the breakdown possibilities of the power adapter.

An improved heat sink structure for car power adapter capable of achieving the above objects comprises: a power adapter, a circuit board, a fan, and a heat sink, wherein an air-in vent is disposed on a lateral side of the power adapter, an air-out vent is disposed on an upper housing of the power adapter, the circuit board is disposed within the power adapter, and the fan is mounted on the circuit board and a heat sink is disposed on the fan. By combining the above components, the present invention of the improved heat sink structure for car power adapter is made. The present invention implements the heat sink with the fan so as to suck cold air into the power adapter through the air-in vent. Since the electronic elements on the circuit board causes high temperature, the heat sink is capable of facilitating the heat removal from the electronic elements of the circuit board and the cold air will enhance the efficiency of heat exchange. Subsequently, the heated air is exhausted to outside through the air-out vent by the fan, thereby prolonging the lifetime and reducing the breakdown possibilities of the heat sink structure for car power adapter.

These features and advantages of the present invention will be fully understood and appreciated from the following detailed description of the present invention in view of the accompanying drawings.

### BRIEF DESCRIPTION OF THE DRAWINGS

FIG. 1 is a three-dimensional exploded view of an improved heat sink structure of car power adapter of the present invention;

FIG. 2 is a three-dimensional partially assembled view of the improved heat sink structure of car power adapter; and

FIGS. 3A and 3B illustrate the implementation of the improved heat sink structure of car power adapter.

### DETAILED DESCRIPTION OF THE PREFERRED EMBODIMENT

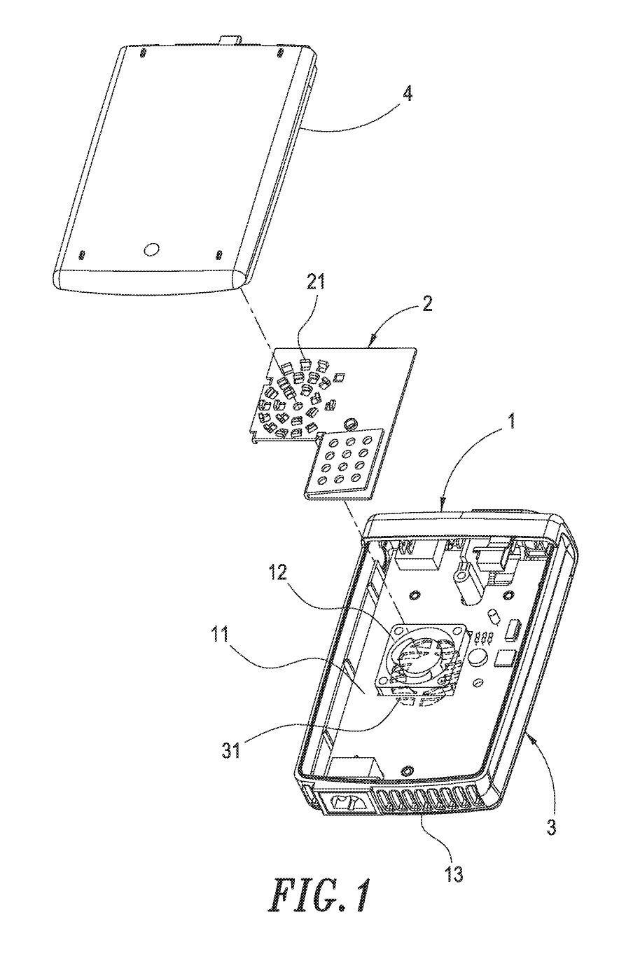

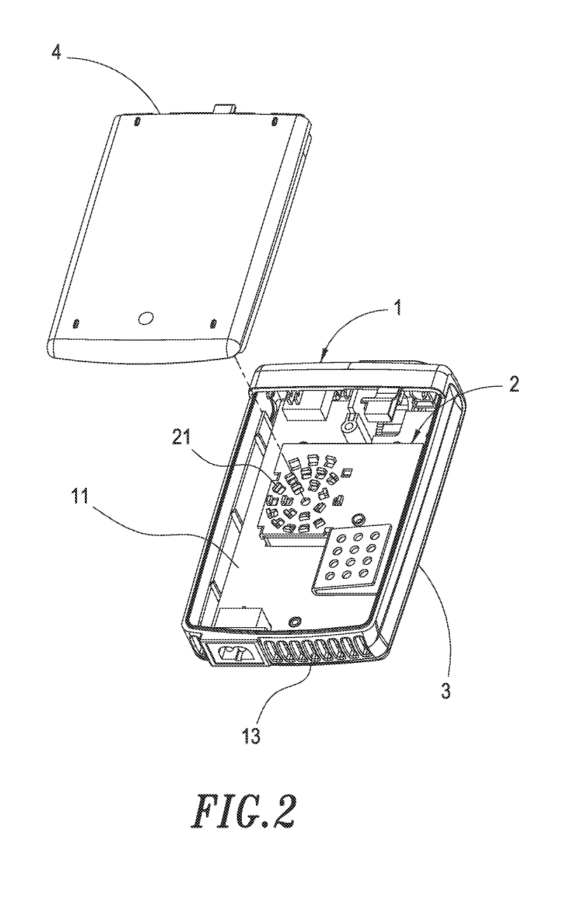

As illustrated in FIGS. 1 and 2, an improved heat sink structure of car power adapter of the present invention comprises:

a power adapter 1 that has a circuit board 11 disposed therein wherein a fan 12 is disposed on the circuit board and an air-in vent 13 is provided on a lateral side of the power adapter 1 for cold air to enter;

a heat sink 2 that is disposed on the fan 12 on the circuit board 11, wherein the heat sink 2 is made of efficient heat conducting material and has at least one fin 21 made of the same material extended directly therefrom, the fin 21 is integrated with the heat sink and is able to rapidly remove the heat from the heat sink 2 to outside, and the size of the heat sink is determined based on the size of the circuit board 11.

an upper housing 3 that is disposed on the top of the power adapter 1, wherein the upper housing 3 provides an air-out vent 31 thereon and the air-out vent 31 is disposed opposite to the fan 12 of the power adapter 1; and

a lower housing 4 that is disposed on the bottom of the power adapter 1.

The power adapter 1 is entirely enclosed by the upper housing 3 and the lower housing 4 disposed above and below the power adapter 1, respectively, to form an improved heat sink structure for car power adapter of the present invention. By combining the heat sink 2 with the fan 12, the heat sink 2 will facilitate heat removal from the electronic components on the circuit board 11 such that the heat sink structure for car power adapter can be effectively improved in terms of its lifetime and the breakdown possibilities.

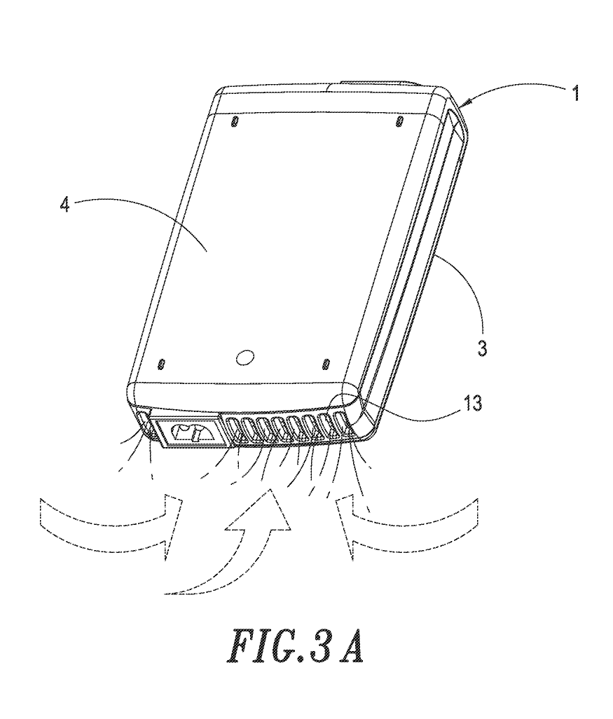

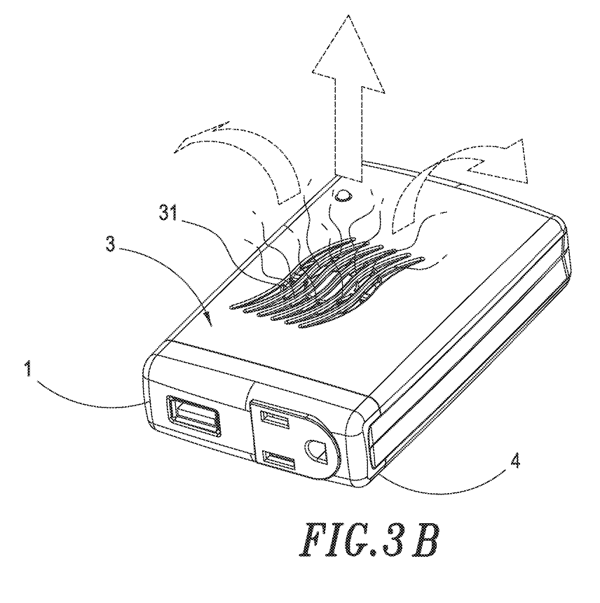

In FIGS. 3A and 3B, the implementation of the improved heat sink structure of car power adapter is illustrated. In view of the drawings, while the power adapter 1 starts to function, the fan 12 therein is simultaneously actuated. The electronic elements on the circuit board 11 of the power adapter 1 will generate heat. Then the heat is efficiently conducted to the heat sink 2 on the circuit board 11. When the fan 1 is actuated, cold air is brought in via the air-in vent 13 to take the heat energy away from the heat sink 2. Subsequently, the heated air is exhausted to outside of the power adapter 1 by the fan 2 through the air-out vent 31 so as to carry out the purpose of rapid heat removal.

In contrast with conventional techniques, the improved heat sink structure of car power adapter of the present invention further provides the following advantages:

1. The present invention provides an improved heat sink structure of car power adapter in which a heat sink and a fan are disposed on the electronic components of the circuit board inside the power adapter and the cold air sucked into the power adapter and passing through the heat sink will take the heat away from the heat sink, and subsequently the heated air will be exhausted out of the power adapter by the fan so as to carry out efficient and rapid heat removal for the electronic components.

2. The present invention provides an improved heat sink structure of car power adapter having advantages in small volume, good heat removing ability, and low manufacturing cost.

3. The present invention provides efficient heat removal so as to improve the lifetime and reduce the breakdown possibilities of the power adapter.

Many changes and modifications in the above described embodiment of the invention can, of course, be carried out without departing from the scope of the invention. Accordingly, to promote the progress in science and the useful arts, the invention is disclosed and is intended to be limited only by the scope of the appended claims.

What is claimed is:

1. A heat sink structure for car power adapter, comprising:
a car power adapter for transforming a car DC power to an AC power; the car power adapter including an upper housing, a lower housing, a circuit board disposed between the upper housing and the lower housing, and a fan arranged on the circuit board, wherein:
a heat sink is disposed on the top of the fan and the heat sink has at least one fin opposite to the fan.

2. The heat sink structure for car power adapter of claim 1, wherein the size of the heat sink is determined based on the size of the circuit board.

3. The heat sink structure for car power adapter of claim 2, wherein the heat sink is capable of rapidly removing heat from the heat sink to outside through the fin.

4. The heat sink structure for car power adapter of claim 1, wherein an air-in vent is provided on a lateral side of the upper housing.

5. The heat sink structure for car power adapter of claim 1, wherein an air-out vent is disposed on the upper housing.

6. The heat sink structure for car power adapter of claim 5, wherein the fan on the circuit board is arranged opposite to the air-out vent of the upper housing.
